(19) United States
(12) Patent Application Publication
(10) Pub. No.: US 2024/0416383 A1
(43) Pub. Date: Dec. 19, 2024

(54) APPARATUS FOR TREATING SUBSTRATE

(71) Applicant: SEMES CO., LTD., Chungcheongnam-do (KR)

(72) Inventors: Ho Jin JANG, Cheonan-si (KR); Jae Hoon PARK, Seongnam-si (KR)

(21) Appl. No.: 18/739,684

(22) Filed: Jun. 11, 2024

(30) Foreign Application Priority Data
Jun. 15, 2023 (KR) 10-2023-0076665

(51) Int. Cl. B05C 11/10; B05C 5/02; B05C 21/00

(52) U.S. Cl. CPC B05C 11/1047; B05C 5/02; B05C 21/00

(57) ABSTRACT

Disclosed is an apparatus for treating a substrate, the apparatus including: an outer cup having a treatment space with an open top; a support unit for supporting a substrate in the treatment space; a guide cup disposed in the treatment space and arranged to surround the support unit; a liquid supply unit for supplying a treatment liquid to a top surface of the substrate supported by the support unit; and a trap ring disposed in a gap between the guide cup and the outer cup to capture the treatment liquid flowing through the gap, in which the trap ring is formed with an exhaust hole through which gas flowing through the gap passes, and the trap ring has a capture space for capturing the treatment liquid on a top surface thereof.

### CROSS-REFERENCE TO RELATED APPLICATIONS

This application claims priority to and the benefit of Korean Patent Application No. 10-2023-0076665 filed in the Korean Intellectual Property Office on Jun. 15, 2023 the entire contents of which are incorporated herein by reference.

### TECHNICAL FIELD

The present invention relates to an apparatus for treating a substrate, and more particularly to an apparatus for liquid-treating a substrate.

### BACKGROUND ART

To manufacture semiconductor devices or flat display panels, various processes, such as deposition, photography, etching, and cleaning, are performed. Among these processes, the photography process includes an application process in which a photosensitive liquid, such as a photoresist, is applied to a surface of a substrate to form a film, an exposure process in which a circuit pattern is transferred to the film formed on the substrate, and a development process in which the film formed on the substrate is selectively removed from the exposed region or an opposite region of the exposed region. Further, a heat treatment process is performed before and after the application process, the exposure process, and the development process.

More recently, high viscosity photoresists have been used as photoresists. High-viscosity photoresist has a high evaporation rate and may be contained in exhaust gases in the form of solid particulates (fume). These particulates are accumulated in areas or pipes of the chamber that provide an exhaust path, clogging a duct and preventing the gas from escaping.

### SUMMARY OF THE INVENTION

The present invention to solve the foregoing problems provides a substrate treating apparatus capable of increasing capture efficiency of a treatment liquid when treating a substrate.

The present invention to solve the foregoing problems also provides a substrate treating apparatus capable of preventing exhaust efficiency from being reduced by a treatment liquid when treating a substrate.

The object of the present invention is not limited thereto, and other objects not mentioned will be clearly understood by those of ordinary skill in the art from the following description.

An exemplary embodiment of the present invention provides an apparatus for treating a substrate, the apparatus including: an outer cup having a treatment space with an open top; a support unit for supporting a substrate in the treatment space; a guide cup disposed in the treatment space and arranged to surround the support unit; a liquid supply unit for supplying a treatment liquid to a top surface of the substrate supported by the support unit; and a trap ring disposed in a gap between the guide cup and the outer cup to capture the treatment liquid flowing through the gap, in which the trap ring is formed with an exhaust hole through which gas flowing through the gap passes, and the trap ring has a capture space for capturing the treatment liquid on a top surface thereof.

According to the exemplary embodiment, the trap ring may include: a first sidewall; and a second sidewall, and the first sidewall is positioned more adjacent to the outer cup than the second sidewall, and the capture space is provided as a space between the first sidewall and the second sidewall.

According to the exemplary embodiment, the first sidewall may be provided to be away from the outer cup as the first sidewall goes downwardly.

According to the exemplary embodiment, second sidewall may be provided to be away from the guide cup as the second sidewall goes downwardly.

According to the exemplary embodiment, the first sidewall may be provided with a downward slope in a direction away from the outer cup, and the second sidewall may be provided with a downward slope in a direction away from the guide cup.

According to the exemplary embodiment, a bottom end of the first sidewall and a bottom end of the second sidewall may be in contact with each other.

According to the exemplary embodiment, at least one of the first sidewall or the second sidewall may be formed with the exhaust hole.

According to the exemplary embodiment, the apparatus may further include: an outer protrusion extending from a top end of the first sidewall in a direction toward the outer cup, and coupled to the outer cup; and an inner protrusion extending from a top end of the second sidewall in a direction toward the guide cup, and coupled to the guide cup.

According to the exemplary embodiment, an inclination angle of the first sidewall and an inclination angle of the second sidewall with respect to an axis perpendicular to the ground may be the same.

According to the exemplary embodiment, the apparatus may further include a ring cleaning unit for supplying a cleaning liquid to clean the trap ring.

According to the exemplary embodiment, the guide cup may include: a top wall provided with a downward slope in a direction toward the outer cup; and an outer wall extending downwardly from the top wall, the outer cup may include a sidewall provided parallel to a perpendicular direction, the trap ring may be positioned between the outer wall and the sidewall, and the ring cleaning unit may further include a ring cleaning nozzle for supplying a cleaning liquid to the top wall.

According to the exemplary embodiment, the outer cup may include: a bottom wall extending inwardly from the sidewall to provide a discharge space for liquid at a lower portion of the guide cup; and a discharge hole connected with the discharge space to discharge the liquid, and the outer wall may be provided in a position opposite the discharge hole.

According to the exemplary embodiment, the treatment liquid may be a photosensitive liquid, and the cleaning liquid may be a thinner.

According to the exemplary embodiment, the photosensitive liquid may have a viscosity of 1000 cP or more.

Another exemplary embodiment of the present invention provides an apparatus for applying a resist liquid onto a substrate, the apparatus including: an outer cup having a treatment space with an open top; a support unit for supporting and rotating a substrate in the treatment space; a guide cup disposed in the treatment space, and arranged to surround the support unit; a liquid supply unit for supplying a resist liquid to a top surface of the substrate supported by the support unit; a trap ring disposed in a gap between the guide cup and the outer cup to capture the treatment liquid flowing through the gap; and a ring cleaning unit for supplying a cleaning liquid to clean the trap ring, in which the trap ring includes: a first sidewall provided with a downward slope in a direction away from the outer cup; and a second sidewall provided with a downward slope in a direction away from the guide cup, a capture space is formed between the first sidewall and the second sidewall to capture the resist liquid that has been scattered from the substrate, and an exhaust hole is formed in at least one of the first sidewall and the second sidewall through which gas flowing through the gap passes.

According to the exemplary embodiment, the cleaning liquid may be a thinner.

According to the exemplary embodiment, the guide cup may include: a top wall provided with a downward slope in a direction toward the outer cup; and an outer wall extending downwardly from the top wall, and the trap ring may be positioned between the outer wall and the sidewall, and the ring cleaning unit may include an intermediate nozzle for supplying a cleaning liquid directly to the top wall.

According to the exemplary embodiment, the outer cup may include: a bottom wall extending from the sidewall in a direction toward the guide cup to form a liquid discharge space at a lower portion of the guide cup; and a discharge hole for discharging the liquid from the discharge space, and the outer wall may be provided in a position opposite the discharge hole, and the bottom wall may be provided with a downward slope toward the discharge hole.

Still another exemplary embodiment of the present invention provides an apparatus for treating a substrate, the apparatus including: an outer cup having a treatment space with an open top; a support unit for supporting a substrate in the treatment space; a guide cup disposed in the treatment space and arranged to surround the support unit; a liquid supply unit for supplying a treatment liquid to a top surface of the substrate supported by the support unit; and a trap ring disposed in a gap between the guide cup and the outer cup to capture the treatment liquid flowing through the gap; and a ring cleaning unit for supplying a cleaning liquid cleaning the trap ring, in which the guide cup includes: a top wall provided with a downward slope in a direction toward the outer cup; and an outer wall extending downwardly from the top wall, and the outer cup may include: a sidewall provided parallel to the outer wall; and a bottom wall extending from the sidewall in a direction toward the guide cup, the bottom wall is formed with a discharging pipe for discharging the treatment liquid and the cleaning liquid, and an exhaust pipe for exhausting the treatment space, the outer wall is provided in a position opposite the discharge hole, and the bottom wall is provided with a downward slope toward the discharge hole, the trap ring may include: a first sidewall; and a second sidewall, the first sidewall is positioned more adjacent to the outer cup than the second sidewall, and a bottom end of the first sidewall and a bottom end of the second sidewall are in contact with each other to provide a capture space for capturing the treatment liquid, and each of the first sidewall and the second sidewall is formed with an exhaust hole through which gas flowing through the gap passes.

According to the exemplary embodiment, the top wall may be formed with a retention groove defined by a first wall, a second wall spaced from the first wall in a direction from the guide cup toward the outer cup, and a bottom surface extending from the first wall and the second wall, a height of the first wall may be provided to be higher than a height of the second wall, the retention grooves may be provided in a plurality in a ring shape along a circumferential direction of the top wall, the retention groove may include: a first retention groove; and a second retention groove spaced from the first retention groove in a direction from the first retention groove toward the outer cup, a bottom surface of the first retention groove may be provided at a higher position than a bottom surface of the second retention groove, and an outer surface of the outer wall may be provided with at least two guide grooves formed downwardly from a bottom end of the top wall.

According to the exemplary embodiments of the present invention, when a substrate is treated with a high viscosity treatment liquid, the efficiency of capturing the treatment liquid may be increased.

According to the exemplary embodiments of the present invention, when a substrate is treated with a high viscosity treatment liquid, it is possible to prevent the exhaust efficiency from being degraded by the treatment liquid.

The effect of the present invention is not limited to the foregoing effects, and the not-mentioned effects will be clearly understood by those skilled in the art from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a perspective view schematically illustrating a substrate treating apparatus according to an exemplary embodiment of the present invention.

FIG. 2 is a front view of the substrate treating apparatus of FIG. 1.

FIG. 3 is a top plan view of an application block in the substrate treating apparatus of FIG. 1.

FIG. 4 is a top plan view of a developing block in the substrate treating apparatus of FIG. 1.

FIG. 5 is a top view schematically illustrating a transfer robot of FIG. 3.

FIG. 6 is a top plan view schematically illustrating an example of a heat treating chamber of FIG. 3.

FIG. 7 is a front view of the heat treating chamber of FIG. 6.

FIG. 8 is a cross-sectional view schematically illustrating an example of a liquid treating chamber according to the exemplary embodiment of the invention of FIG. 3.

FIG. 9 is a perspective view schematically illustrating an example of a trap ring according to the exemplary embodiment of the present invention.

FIG. 10 is a cross-sectional enlarged view of the trap ring of FIG. 8 installed.

FIG. 11 is a diagram illustrating a nozzle provided in a ring cleaning unit according to the exemplary embodiment of the present invention.

FIGS. 12 to 14 are flowcharts illustrating a process for cleaning a photoresist solution using a trap ring.

FIG. 15 is a cross-sectional view schematically illustrating an example of a liquid treating chamber according to another exemplary embodiment of the present invention.

FIG. 16 is a perspective view illustrating a guide cup from FIG. 15.

FIG. 17 is a cross-sectional view illustrating a top wall of the guide cup of FIG. 15.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., +10%).

When the terms “about” or “substantially” are used in connection with a numerical value, it should be understood that the associated numerical value includes a manufacturing or operational tolerance (e.g., +10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be processed. However, the technical spirit of the present invention may be applied to devices used for other types of substrate treatment, in addition to wafers.

Hereinafter, exemplary embodiments of the present invention will be described with reference to the accompanying drawings.

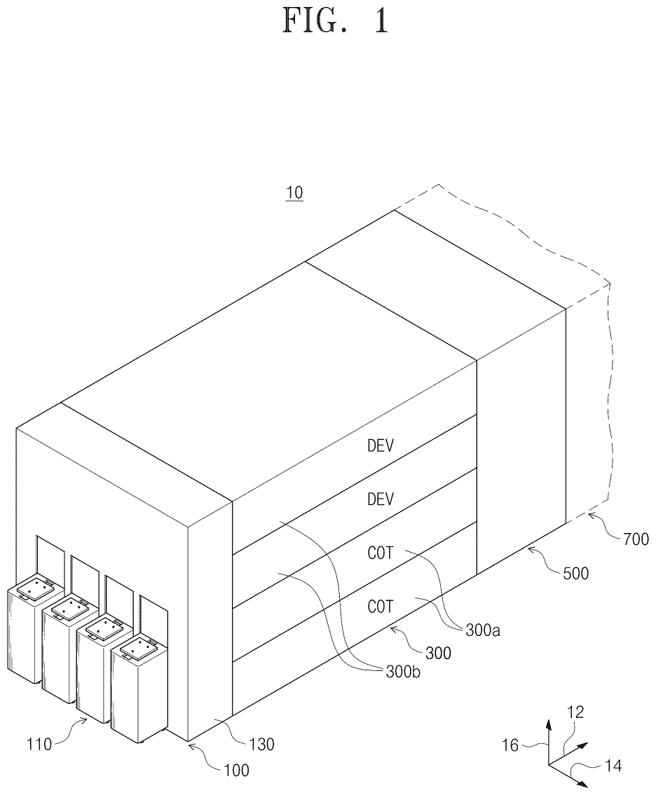

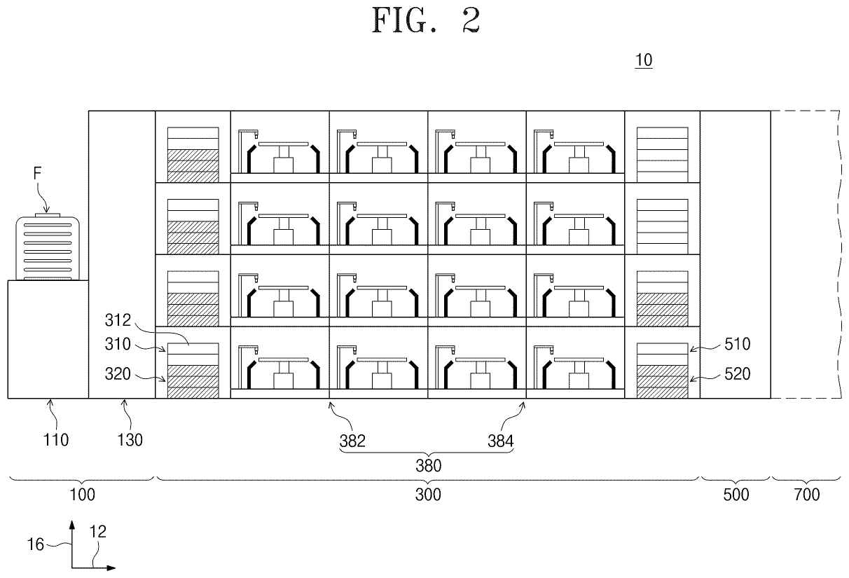

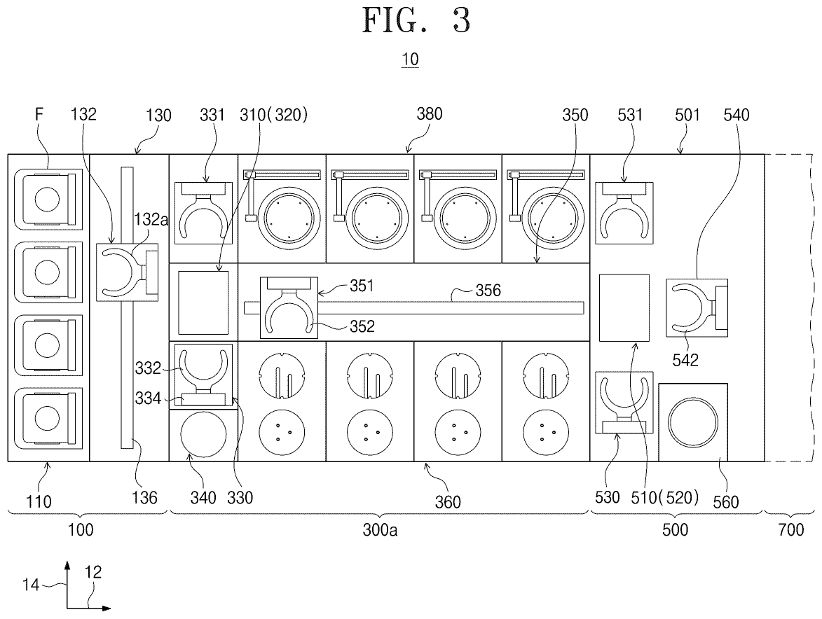

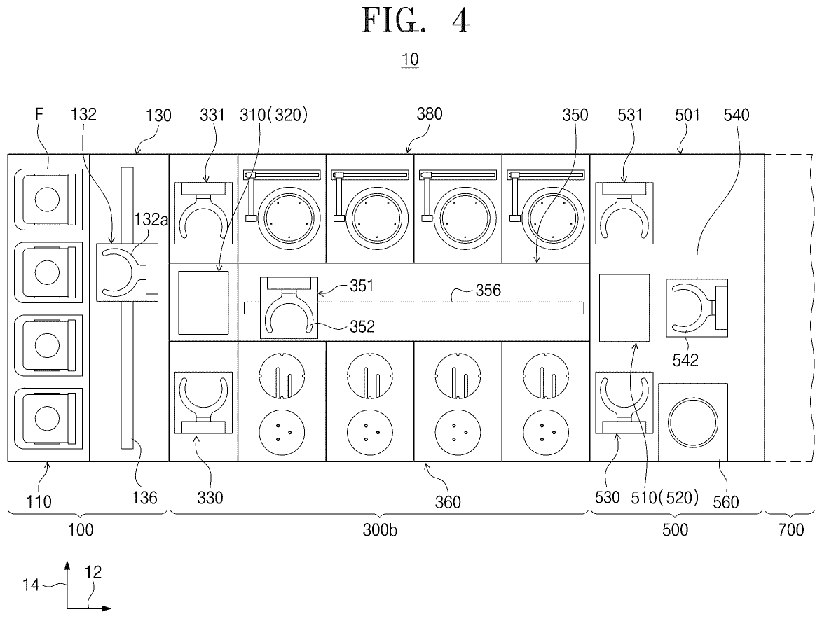

FIG. 1 is a perspective view schematically illustrating a substrate treating apparatus according to an exemplary embodiment of the present invention, and FIG. 2 is a front view of the substrate treating apparatus of FIG. 1. FIG. 3 is a top plan view of an application block in the substrate treating apparatus of FIG. 1, and FIG. 4 is a top plan view of a developing block in the substrate treating apparatus of FIG. 1.

Referring to FIGS. 1 to 4, a substrate treating apparatus 10 includes an index module 100, a treating module 300, and an interface module 500. According to the exemplary embodiment, the index module 100, the treating module 300, and the interface module 500 are sequentially arranged in series. Hereinafter, a direction in which the index module 100, the processing module 300, and the interface module 500 are arranged is defined as a first direction 12, a direction perpendicular to the first direction 12 when viewed from above is defined as a second direction 14, and a direction perpendicular to both the first direction 12 and the second direction 14 is defined as a third direction 16.

The index module 100 is provided for transferring a substrate W between a container F in which the substrate W is accommodated and the processing module 300. A longitudinal direction of the index module 100 is provided in the second direction 14. The index module 100 includes a load port 110 and an index frame 130. The container F in which the substrates W are accommodated is placed on the load port 110. The load port 110 is located on the opposite side of the processing module 300 relative to the index frame 130. A plurality of load ports 110 may be provided, and the plurality of load ports 110 may be disposed along the second direction 14. In an example, as the container F, an airtight container F, such as a Front Open Unified Pod (FOUP), may be used. The container F may be placed on the load port 110 by a transfer means (not illustrated), such as an overhead transfer, an overhead conveyor, or an automatic guided vehicle, or an operator.

An index robot 132 is provided inside the index frame 130. Within the index frame 130, a guide rail 136 is provided. A longitudinal direction of the guide rail 136 is provided in the second direction 14. The index robot 132 is mounted on the guide rail 136 so as to be movable along the guide rail 136. The index robot 132 includes a hand 132a on which the substrate W is placed. The hand 132a may be provided to be movable forwardly and backwardly, movable linearly along the third direction, and rotatably movable about the axis of the third direction 16.

The treating module 300 performs an application process and a development process on the substrate W. The processing module 300 includes a coating block 300a and a developing block 300b.

The application block 300a performs an application process on the substrate W before the exposure process. The developing block 300b performs a development process on the substrate W after the exposure process. A plurality of application blocks 300a is provided. The plurality of application blocks 300a may be provided while being stacked on top of each other. A plurality of developing blocks 300b is provided. The plurality of developing blocks 300b may be provided to be stacked with each other. In one example, two application blocks 300a are provided and two developing blocks 300b are provided. The plurality of application blocks 300a may be positioned below the developing blocks 300b.

In one example, the plurality of application blocks 300a may be provided with structures that are identical to each other. A film applied to the substrate W in each of the plurality of application blocks 300a may be the same type of film. Optionally, the films applied to the substrate W by each application block 300a may be different types of films. The film applied to the substrate W includes a photoresist film. The film applied to the substrate W may further include an anti-reflective film. Optionally, the film applied to the substrate W may further include a protective film.

Additionally, the two developing blocks 300b may be provided with the same structures as each other. A developer supplied to the substrate W in the plurality of developer blocks 300b may be the same type of liquid. Optionally, the developer supplied to the substrate W may be different types of developer depending on the developing blocks 300b. For example, a process for removing a light-irradiated region in a region of a register film on the substrate W may be performed in one of the two developing blocks 300b, and a process for removing a non-irradiated region may be performed in the other of the two developing blocks 300b.

Referring to FIG. 3, the application block 300a includes a buffer unit 310, a cooling unit 320, a hydrophobization chamber 340, a transfer chamber 350, a heat treating chamber 360, and a liquid treating chamber 380.

The buffer unit 310, the cooling unit 320, and the hydrophobization chamber 340 are disposed adjacent to the index block 100. The hydrophobization chamber 340 and the buffer unit 310 may be sequentially disposed along the second direction 14. In addition, the cooling unit 320 and the buffer unit 310 may be provided to be stacked on top of each other in a vertical direction.

The buffer unit 310 includes one or a plurality of buffers 312. When a plurality of buffers 312 is provided, the plurality of buffers 312 may be arranged to be stacked on top of each other. The buffer 312 provides a space for the substrate W to stay when the substrate W is transferred between the index module 100 and the processing module 300. The hydrophobization chamber 340 provides a hydrophobization treatment to the surface of the substrate W. The hydrophobization treatment may be performed prior to performing an application process on the substrate W. The hydrophobization treatment may be accomplished by supplying hydrophobizing gas to the substrate W while heating the substrate W. The cooling unit 320 cools the substrate W. The cooling unit 320 includes one or more cooling plates. When a plurality of cooling plates is provided, the plurality of cooling plates may be arranged to be stacked on top of each other. In one example, the cooling unit 320 may be disposed below the buffer unit 310. The cooling plate may have a flow path through which coolant flows. The substrate W after the hydrophobization treatment may be cooled on the cooling plate.

A transfer mechanism 330 is provided between the hydrophobization chamber 340 and the buffer unit 310 and between the hydrophobization chamber 340 and the cooling unit 320. The transfer mechanism 330 is provided for transferring the substrate W between the buffer unit 310, the hydrophobization chamber 340, and the cooling unit 320.

The transfer mechanism 330 includes a hand 332 on which the substrate W is placed, and the hand 332 may be provided to be movable forwardly and backwardly, rotatable about the third direction 16, and movable along the third direction 16. In one example, the transfer mechanism 330 is moved in the third direction 16 along a guide rail 334. The guide rail 334 extends from an application block located at the lowest of the application blocks 300a to a developing block located at the highest of the developing blocks 300b. This allows the transfer mechanism 330 to transfer the substrate W between the blocks 300a and 300b provided on different layers. For example, the transfer mechanism 330 may transfer the substrate W between the application blocks 300a and 300b provided on different layers. The transfer mechanism 330 may also transfer the substrate W between the application block 300a and the developing block 300b.

In addition, another transfer unit 331 may be further provided on the opposite side of the side where the hydrophobization chamber 340 is provided relative to the buffer unit 310. Another transfer unit 331 may be provided to transfer the substrate W between the buffer unit 310 and the cooling unit 320 provided in the same block 300a and 300b. Further, another transfer unit 331 may be provided to transfer the substrate W between the buffer unit 310 and the cooling unit 320 provided in different blocks 300a and 300b.

The transfer chamber 350 is provided so that a longitudinal direction thereof is parallel to the first direction 12. One end of the transfer chamber 350 may be located adjacent to the buffer unit 310 and/or the cooling unit 320. The other end of the transfer chamber 350 may be positioned adjacent to the interface module 500.

A plurality of heat treating chambers 360 is provided. Some of the heat treating chambers 360 are disposed along the first direction 12. Additionally, some of the heat treating chambers 360 may be stacked along the third direction 16. The heat treating chambers 360 may all be located on one side of the transfer chamber 350.

The liquid treating chamber 380 performs a liquid film formation process to form a liquid film on the substrate W. In one example, the liquid film forming process includes a resist film forming process. The liquid film forming process may include an anti-reflective film forming process. Optionally, the liquid film forming process may further include a protective film forming process. A plurality of liquid treating chambers 380 is provided. The liquid treating chambers 380 may be located on opposite sides of the heat treating chamber 360. For example, all of the liquid treating chambers 380 may be located on the other side of the transfer chamber 350. The liquid treating chambers 380 are arranged side-by-side along the first direction 12. Optionally, some of the liquid treating chambers 360 may be stacked along the third direction 16.

In one example, the liquid treating chambers 380 include a front end liquid treating chamber 380a and a rear end liquid treating chamber 380b. The front end liquid treating chamber 380a is disposed relatively close to the index module 100, and the rear end liquid treating chamber 380b is disposed further close to the interface module 500.

The front end liquid treating chamber 380a applies a first liquid to the substrate W, and the rear end liquid treating chamber 380b applies a second liquid to the substrate W. The first liquid and the second liquid may be different types of liquid. In one example, the first liquid may be a liquid for forming an anti-reflective film and the second liquid may be a liquid for forming a photoresist film. The photoresist film may be formed on a substrate W to which an anti-reflective film has been applied. Optionally, the first liquid may be a liquid for forming a photoresist film, and the second liquid may be a liquid for forming an antireflective film. In this case, the anti-reflective film may be formed on the substrate W on which the photoresist film is formed. Optionally, the first liquid and the second liquid may be the same kind of liquid, and they may both be liquids for forming the photoresist film.

Referring to FIG. 4, the developing block 300B includes a buffer unit 310, a cooling unit 320, a transfer chamber 350, a heat treating chamber 360, and a liquid treating chamber 380. The arrangement of the buffer unit 310, the cooling unit 320, the transfer chamber 350, the heat treating chamber 360, and the liquid treating chamber 380 in the developing block 300b may be the same as the arrangement of the buffer unit 310, the cooling unit 320, the transfer chamber 350, the heat treating chamber 360, and the liquid treating chamber 380 in the application block 300a. When viewed from above, the buffer unit 310, the cooling unit 320, the transfer chamber 350, the heat treating chamber 360, and the liquid treating chamber 380 in the developing block 300b and the buffer unit 310, the cooling unit 320, the transfer chamber 350, the heat treating chamber 360, and the liquid treating chamber 380 in the application block 300 may be disposed in overlapping positions.

The heat treating chamber 360 performs a heating process on the substrate W. The heating process includes a post-exposure baking process performed on the substrate W after the exposure process is completed, and a hard baking process performed on the substrate W after the development process is completed.

The liquid treating chamber performs the development process by supplying a developer onto the substrate W and developing the substrate W.

In FIG. 3 or FIG. 4, the transfer chamber 350 is provided with a transfer robot 351. The transfer robot 351 transfers the substrate W between the buffer unit 310, the cooling unit 320, the heat treating chamber 360, the liquid treating chamber 380, and the buffer unit 510 or the cooling unit 520 of the interface module 500. In one example, the transfer robot 351 includes a hand 352 on which the substrate W is placed. The hand 352 may be provided to be movable forwardly and backwardly, rotatable about the third direction 16, and movable along the third direction 16. A guide rail 356, of which a longitudinal direction is parallel to the first direction 12, is provided within the transfer chamber 350, and the transfer robot 351 may be provided to be movable on the guide rail 356.

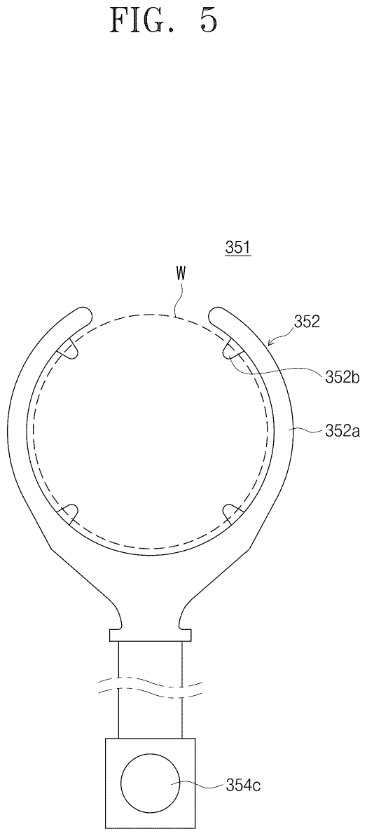

FIG. 5 is a diagram illustrating one example of the hand of the transfer robot. Referring to FIG. 5, the hand 352 includes a base 352a and a support protrusion 352b. The base 352a may have an annular ring shape in which a portion of the circumference is bent. The base 352a has an inner diameter greater than the diameter of the substrate W. The support protrusion 352b extends inwardly from the base 352a. A plurality of support protrusions 352b is provided, and supports an edge region of the substrate W. In one example, support protrusions 352b may be provided in four equally spaced rows.

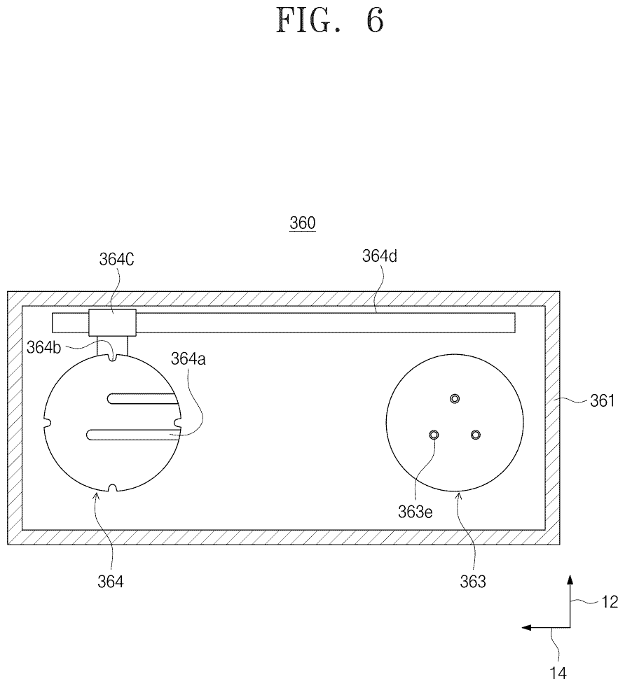

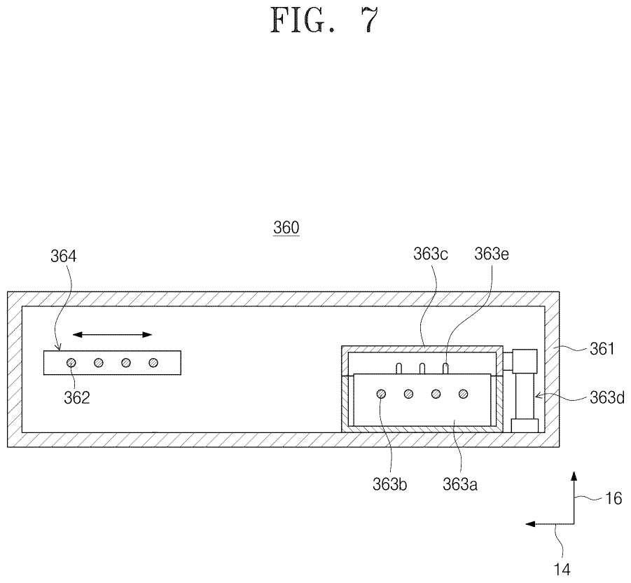

FIG. 6 is a top plan view schematically illustrating an example of the heat treating chamber of FIG. 3, and FIG. 7 is a front view of the heat treating chamber of FIG. 6.

Referring to FIGS. 6 and 7, the heat treating chamber 360 includes a housing 361, a heating unit 363, and a transfer plate 364.

The housing 361 is provided in the shape of a generally rectangular parallelepiped. In the sidewall of the housing 361, an entrance opening (not illustrated) is formed through which the substrate W enters and exits. The entrance opening may remain open. Optionally, a door (not illustrated) may be provided to open and close the entrance opening. The heating unit 363 and the transfer plate 364 are provided within the housing 361.

The heating unit 323 includes a heating plate 363a, a cover 363c, and a heater 323b. The heating plate 363a has a generally circular shape when viewed from the top. The heating plate 363a has a larger diameter than the substrate W. The heater 363b is installed on the heating plate 363a. The heater 363b may be provided as a heating wire or heating pattern that is heated by the supply of electrical power. The heating plate 363a is provided with a lift pin 363e. The lift pin 363e is provided to be movable in an upward and downward direction along the third direction 16. The lift pin 363e receives the substrate W from the transfer robot 352 and places the received substrate W on the heating plate 363a, or lifts the substrate W from the heating plate 363a and hands the substrate over to the transfer robot 352. According to the example, three lift pins 363e may be provided. The cover 363c has a space with an open lower portion therein. The cover 363c is located above the heating plate 363a and is moved in a vertical direction by a driver 363d. The space formed by the cover 363c and the heating plate 363a according to the movement of the cover 363c is provided as a heating space for heating the substrate W.

The transfer plate 364 is provided in a substantially disk shape, and has a diameter corresponding to that of the substrate W. A notch 364b is formed at an edge of the transfer plate 364. The notch 364b may have a shape that corresponds to the protrusion 352b formed on the hands of the transfer robot 352 described above. Further, the notches 364b are provided in a number corresponding to the protrusions 352b formed on the hand, and are formed at locations corresponding to the protrusions 352b. In a position in which the hand and the transfer plate 364 are arranged in the vertical direction, the substrate W is transferred between the hand 354 and the transfer plate 364 when the vertical position of the hand and the transfer plate 364 is changed. The transfer plate 364 is mounted on a guide rail 364d, and may be movable along the guide rail 364d by the driver 364c.

A plurality of slit-shaped guide grooves 364a is provided in the transfer plate 364. The guide grooves 364a extend from a distal end of the transfer plate 364 to an interior of the transfer plate 364. The longitudinal direction of the guide groove 364a is provided along the second direction 14, and the guide grooves 364a are spaced apart from each other along the first direction 12. The guide groove 364a prevents the transfer plate 364 and the lift pins 363e from interfering with each other when the substrate W is transferred between the transfer plate 364 and the heating unit 363.

The transfer plate 364 is provided with a thermally conductive material. In one example, the transfer plate 364 may be provided from a metal material.

A cooling channel 364 is formed in the transfer plate 364. The cooling channel 364 is supplied with coolant. The substrate W, which has been heated in the heating unit 363, may be cooled while being transferred by the transfer plate 364. Also, the substrate W may be cooled on the transfer plate 364 while the transfer plate 364 is stopped for the substrate W to be taken over by the transfer robot 351.

Optionally, a cooling unit may be further provided within the housing 361. In this case, the cooling unit may be arranged in parallel with the heating unit 363. The cooling unit may be provided as a cooling plate having a passage formed therein through which coolant flows. The substrate that has been heated in the heating unit may be returned to the cooling unit for cooling.

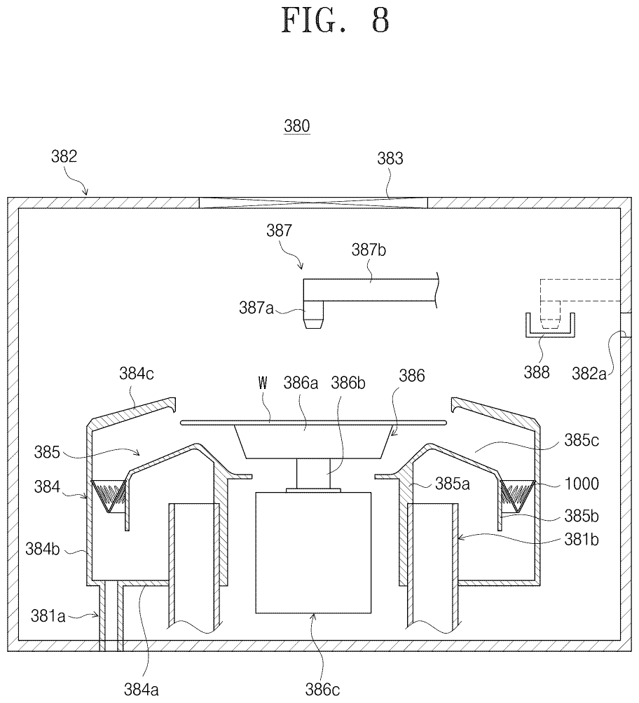

FIG. 8 is a front view schematically illustrating the liquid treating chamber of FIG. 3.

Referring to FIG. 8, the liquid treating chamber 380 includes a housing 382, an outer cup 384, a guide cup 385, a support unit 386, a liquid supply unit 387, a trap ring 1000, and a ring cleaning unit 2000.

The housing 382 is provided in a rectangular cylindrical shape having an inner space. An opening 382a is formed in one side of the housing 382. The opening 382a functions as a passageway through which the substrate W enters and exits. A door (not illustrated) is installed in the opening 382a, and the door opens and closes the opening.

An inner space of the housing 382 is provided with the outer cup 384. The outer cup 384 has a treatment space with an open top.

A support unit 386 supports the substrate W within the treatment space of the outer cup 384. The support unit 386 includes has a support plate 386a, a rotation shaft 386b, and a driver 386c. The support plate 386a is provided with a circular top surface. The support plate 386a has a diameter smaller than the substrate W. The support plate 386a is provided to support the substrate W by vacuum pressure. The rotation shaft 386b is coupled to the center of the lower surface of the support plate 386a, and the driver 386c is provided on the rotation shaft 386b to provide rotational force to the rotation shaft 386b. The driver 386c may be a motor. Additionally, a lifting driver (not illustrated) may be provided to adjust the relative height of the support plate 386a and the outer cup 384.

The liquid supply unit 387 supplies the treatment liquid onto the substrate W. When the liquid treating chamber 380 is provided in the application block 300a, the treatment liquid may be a liquid for forming a photoresist film, an anti-reflective film, or a protective film. The photoresist film may have a viscosity of 1000 cP or more. If the liquid treating chamber 380 is provided in the developing block 300b, the treatment liquid may be a developer liquid. The liquid supply unit 387 has a nozzle 387a, a nozzle support 387b, and a liquid supply source (not illustrated). The nozzle 387a discharges the treatment liquid onto the substrate W. The nozzle 387a is supported on a nozzle support 387b. The nozzle support 387b moves the nozzle 387a between a process position and a standby position. In the process position, the nozzle 387a supplies the treatment liquid to the substrate W placed on the support plate 386a, and after completing the supply of the treatment liquid, the nozzle 387a waits in the standby position. In the standby position, the nozzle 387a waits at a groove port 388, and the groove port 388 is located on the outside of the outer cup 384 within the housing 382.

On the top wall of the housing 382 is disposed a fan filter unit 383 that supplies a downward airflow to the interior space. The fan filter unit 383 has a fan that introduces air from the outside into the inner space and a filter that filters the air from the outside.

The outer cup 384 has a bottom wall 384a, a sidewall 384b, and a top wall 384c. The interior of the outer cup 384 is provided with an interior space as described above. The interior space includes a treatment space at the top and an exhaust space at the bottom.

The bottom wall 384a is provided in a circular shape and has an opening in the center. The bottom wall 384a extends inwardly from the sidewall 384b. The bottom wall 384a forms a liquid discharge space in the lower portion of the guide cup 385. A discharge hole 384d is formed in the bottom wall 384a to discharge the treatment liquid. The discharge hole 384d may be provided in a position opposite to the trap ring 1000, which will be described later. The sidewall 384b extends upwardly from the outer end of the bottom wall 384a. The sidewall 384b is provided in a ring shape and is provided vertical to the bottom wall 384a. Alternatively, the sidewall 384b may be provided parallel to the perpendicular direction. In one example, the sidewall 384b extends to a height equal to the top surface of the support plate 386a, or extends to a height slightly lower than the top surface of the support plate 386a. The top wall 384c has a ring shape, with an opening in the center. The top wall 384c is provided with an upward slope from the top of the sidewall 384b toward the center axis of the outer cup 384.

The guide cup 385 is positioned on the inner side of the outer cup 384. The guide cup 385 has an inner wall 385a, an outer wall 385b, and a top wall 385c. The guide cup 385 is disposed to surround the support unit 386. The inner wall 385a has a through hole that is perforated in the vertical direction. The inner wall 385a is arranged to surround the driver 386c. The inner wall 385a minimizes the exposure of the driver 386c to the airflow 84 in the treatment space. The rotational shaft 386b and/or the driver 386c of the support unit 386 extend in the vertical direction through the through-hole. The outer wall 385b is spaced apart from the inner wall 385a and is disposed to surround the inner wall 385a. The outer wall 385b is spaced apart from the sidewall 384b of the outer cup 384. The outer wall 385b extends downwardly from the top wall 385c, which will be described later. The inner wall 385a is spaced upwardly from the bottom wall 384a of the outer cup 384. The top wall 385c connects the upper end of the outer wall 385b with the upper end of the inner wall 385a. The top wall 385c has a ring shape and is disposed to surround the support plate 386a. The top wall 385c is provided with a downward slope in a direction facing the outer cup 384. In one example, the top wall 385c has an upwardly convex shape. In another exemplary embodiment, the space below the support plate 386a in the treatment space may be provided as an exhaust space. In one example, the exhaust space may be defined by the guide cup 385. The space surrounded by the outer wall 385b, the top wall 385c, and the inner wall 385a of the guide cup 385 and/or the space below the space may be provided as the exhaust space.

The discharge hole 384d of the outer cup 384 is connected to a discharge pipe 381a for discharging the treatment liquid. In addition, the bottom wall 384a of the outer cup 384 may be connected to an exhaust pipe 381b that exhausts the treatment space from the inner side of the outer wall 385b.

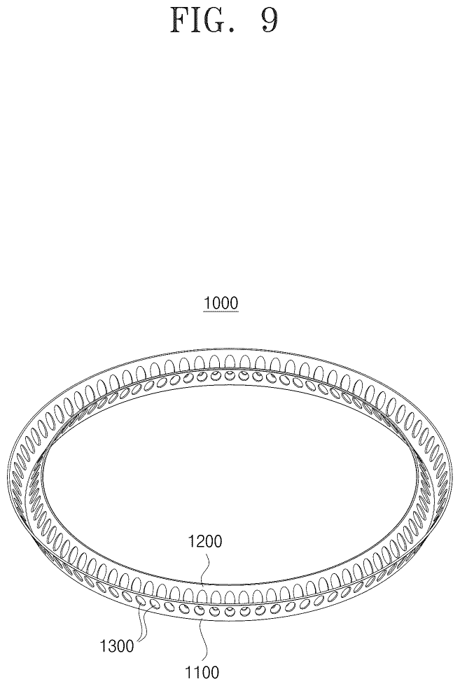

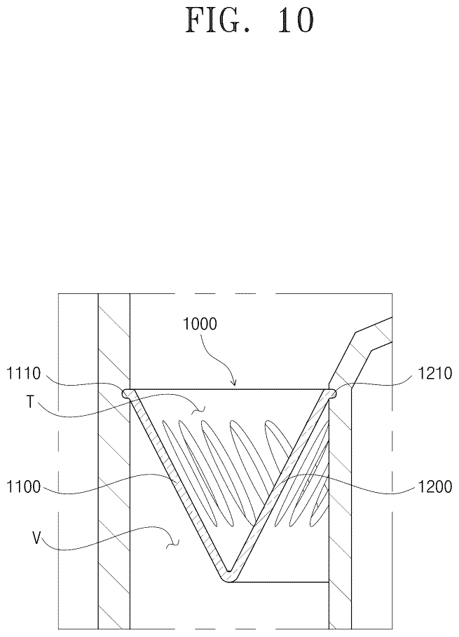

FIG. 9 is a perspective view of the trap ring according to the exemplary embodiment of the present invention, and FIG. 10 is a cross-sectional enlarged view of the trap ring of FIG. 8 installed. The trap ring 1000 is disposed in a gap V between the guide cup 385 and the outer cup 384. The trap ring 1000 captures the treatment liquid flowing through the gap V. In one example, the trap ring 1000 is positioned in the gap V between the outer wall 385b of the guide cup 385 and the sidewall 384b of the outer cup 384. A capture space T is formed on the top surface of the trap ring 1000 to capture the treatment liquid. An exhaust hole 1300 is formed in the trap ring 1000 through which gas flowing through the gap V passes. In one example, the exhaust hole 1300 is formed on the side of the capture space T. In one example, the trap ring 1000 may include a first sidewall 1100 and a second sidewall 1200. The first sidewall 1100 is positioned closer to the sidewall 384b of the outer cup 384 than the second sidewall 1200. The space between the first sidewall 1100 and the second sidewall 1200 may provide the capture space T. The first sidewall 1100 and the second sidewall 1200 are each provided with an inclined surface with respect to the ground. The first sidewall 1100 is provided to be away from the outer cup 384 as the first sidewall 1100 goes downwardly. The second sidewall 1200 is provided to be away from the guide cup 385 downwardly. The first sidewall 1100 and the second sidewall 1200 may be provided at the same angle to the ground. In one example, the bottom end of the first sidewall 1100 and the bottom end of the second sidewall 1200 may be in contact with each other. The exhaust hole 1300 is formed in at least one of the first sidewall 1100 and the second sidewall 1200. In one example, the exhaust holes 1300 may be provided in both the first sidewall 1100 and the second sidewall 1200. The exhaust holes 1300 may be formed in a lower region of the first sidewall 1100. The exhaust holes 1300 are formed at a location spaced apart from the bottom end of the first sidewall 1100. The exhaust holes 1300 are provided in a plurality along a circumferential direction of the first sidewall 1100. The exhaust holes 1300 may each be formed in a circular shape. The exhaust holes 1300 may be provided with the same size. The exhaust holes 1300 may be equally spaced apart. The exhaust holes 1300 formed in the second sidewall 1200 may be provided in the same size and same arrangement as the exhaust holes 1300 formed in the first sidewall 1100. The exhaust holes 1300 are provided to be spaced apart from the bottom ends of the first sidewall 1100 and the second sidewall 1200 in the upward direction. It is sufficient if the exhaust holes 1300 are provided at a height such that a certain amount of treatment liquid and cleaning liquid may be captured in the capture space T of the trap ring 1000. Furthermore, the exhaust holes 1300 may be provided in a plurality. The interval between the exhaust holes 1300 may be provided to be constant. An outer protrusion 1210 is formed at the top of the first sidewall 1100. The outer protrusion 1210 extends from the top of the first sidewall in a direction toward the outer cup 384. The outer protrusion 1210 is coupled to the guide cup 385. The outer protrusion 1210 may be inserted into a groove formed in the sidewall 384b of the outer cup 384. At the top of the second sidewall 1200, an inner protrusion 1110 is formed. The inner protrusion 1110 extends from the top of the second sidewall in a direction toward the guide cup 385. The inner protrusion 1110 is coupled to the outer cup 384. The inner protrusion 1110 may be inserted into a groove formed in the outer wall 385b of the guide cup 385. The inner protrusion 1110 and the outer protrusion 1210 may be provided at the same height.

Further, the apparatus may be provided with a removal liquid nozzle 2200. The removal liquid nozzle 2200 supplies a cleaning liquid that removes a film from an edge region of the top surface of the substrate W. Additionally, the apparatus may be provided with a backside cleaning nozzle 2300. The backside cleaning nozzle 2300 supplies a cleaning liquid to the underside of the substrate W.

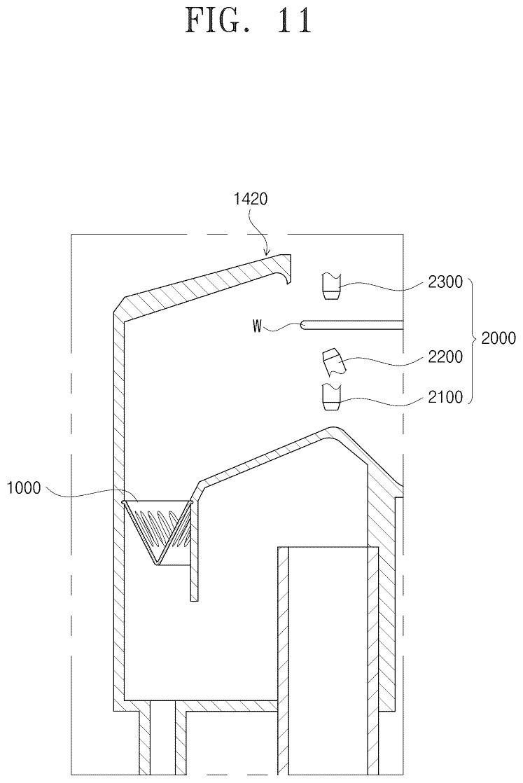

FIG. 11 is a diagram illustrating a nozzle provided in the ring cleaning unit according to the exemplary embodiment of the present invention. The ring cleaning unit 2000 cleans a trap ring. The ring cleaning unit 2000 includes a ring cleaning nozzle 2100 that supplies a cleaning liquid. For example, the removal liquid may be a thinner. In one example, the ring cleaning nozzle 2100 may supply a cleaning liquid to the top wall 385 of the guide cup 385. The removal liquid nozzle 2200 and the backside cleaning nozzle 2300 described above may function as a ring cleaning unit 2000 to clean the trap ring 1000.

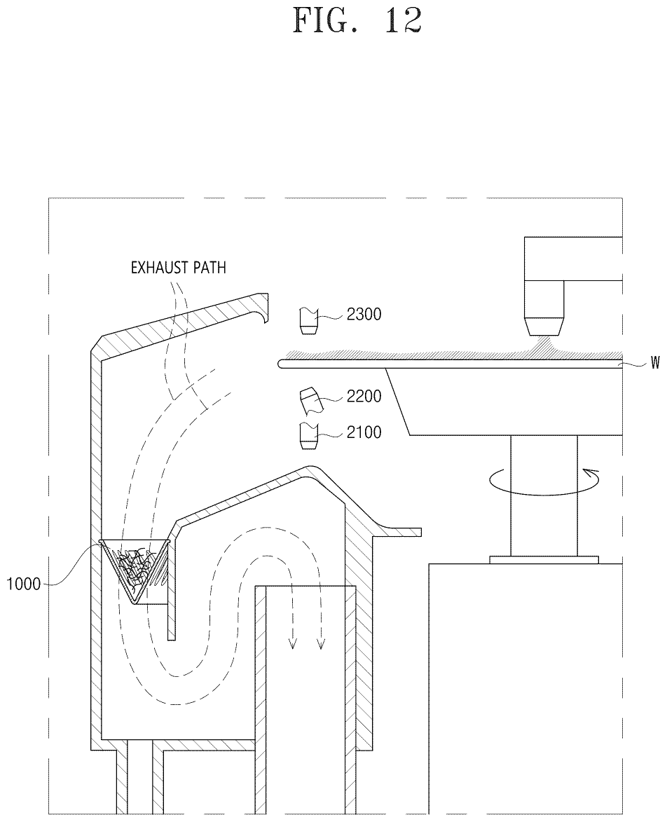

FIGS. 12 to 14 are flowcharts illustrating a process for cleaning a photoresist solution using the trap ring. Referring to FIG. 12, during the application process, the liquid supply unit 387 supplies a photoresist solution to the substrate W supported on the support unit 386. The driving unit of the support unit 386 rotates the substrate, and the photoresist solution is applied to the substrate W. The unapplied photoresist solution are scattered toward the top wall 384c and the sidewall 384b of the outer cup 384. The scattered photoresist solution is captured in the trap ring 1000. When the photoresist solution has a high viscosity, the photoresist solution may agglomerate into a thread-like shape and be scattered. Gas may be supplied during the application process. Also, gas may be generated during the application process. The gas is exhausted along an exhaust path. The exhaust path includes an exhaust hole 1300 and an exhaust pipe 381b.

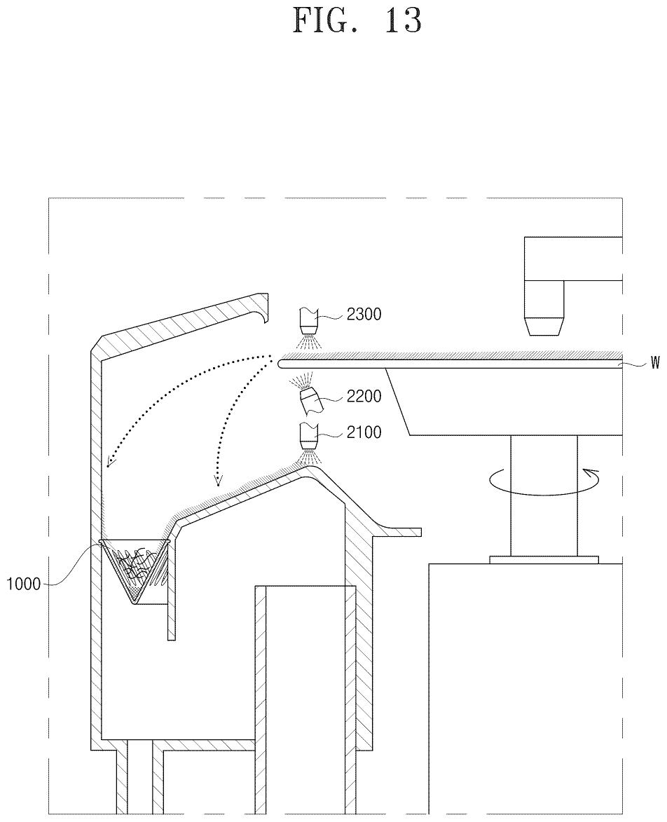

Referring to FIG. 13, a removal process is performed after the application process. During the removal process, a film is removed from the edge region in the top surface of the substrate W. The removal liquid nozzle 2200 supplies a cleaning liquid to the edge region of the top surface of the substrate W. The cleaning liquid removes the film from the edge region of the substrate W. The cleaning process cleans any residual contaminants on the underside of the substrate W during the cleaning process. The backside cleaning process may be performed after the removal process. Alternatively, the backside cleaning process may be performed simultaneously with the removal process. The backside cleaning nozzle 2300 supplies a cleaning liquid to the underside of the substrate W. The cleaning liquid cleans the underside of the substrate W. For example, the removal liquid may be a thinner. During the removal process and the backside cleaning process, the substrate is rotated by the support unit 385.

During the ring cleaning process, the trap ring 1000 is cleaned. The ring cleaning process may be performed after the removal process and the backside cleaning process. Optionally, the ring cleaning process may be performed during any one of the application process, the removal process, or the backside cleaning process. Optionally, the ring cleaning process may be performed during the application process, the removal process, and the backside cleaning process. The ring cleaning nozzle 2100 supplies the cleaning liquid directly to the top wall 385 of the guide cup 385. The cleaning liquid cleans any photoresist solution remaining on the top wall 385 of the guide cup 385. The cleaning liquid also flows into the trap ring 1000 to clean the captured photoresist solution.

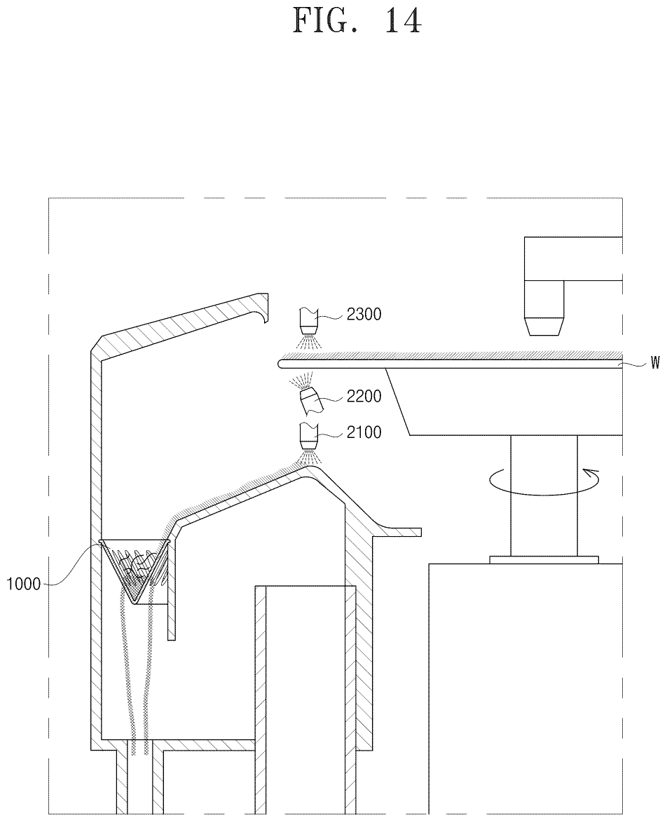

Referring to FIG. 14, the photoresist solution may be cleaned by being dissolved in the cleaning liquid. The cleaning liquid is scattered onto the top wall 384c or sidewall 384b of the outer cup 384 by rotation of the substrate W. The scattered cleaning liquid is captured in the trap ring 1000. The captured photoresist solution is dissolved in the cleaning liquid and cleaned. The cleaning liquid in which the photoresist solution is dissolved is discharged to the exhaust hole 1300 or captured in the capture space T of the trap ring 1000. The application process, removal process, and backside cleaning process are repeated. During the iteration, the cleaning liquid accumulates in the capture space T of the trap ring 1000. The accumulated cleaning liquid may dissolve the photoresist solution that has been scattered. The cleaning liquid may be retained in the capture space up to the height at which the exhaust holes 1300 are formed. When a greater amount of cleaning liquid is stored within the capture space over the height of the exhaust holes, the cleaning liquid is discharged out of the capture space through the exhaust holes. The discharged cleaning liquid is discharged to the outside through the discharge pipe 381a formed in the bottom wall 384a corresponding to the position of the trap ring 1000. In this way, the trap ring 1000 may efficiently capture and clean the photoresist solution and the cleaning liquid through the capture space T. When the photoresist is a high-viscosity photoresist of 1000 cP or more, even though a high-viscosity photoresist solution is used, the photoresist solution may be cleaned to suppress the generation of fume, thereby preventing the accumulation of photoresist particulates in the exhaust path.

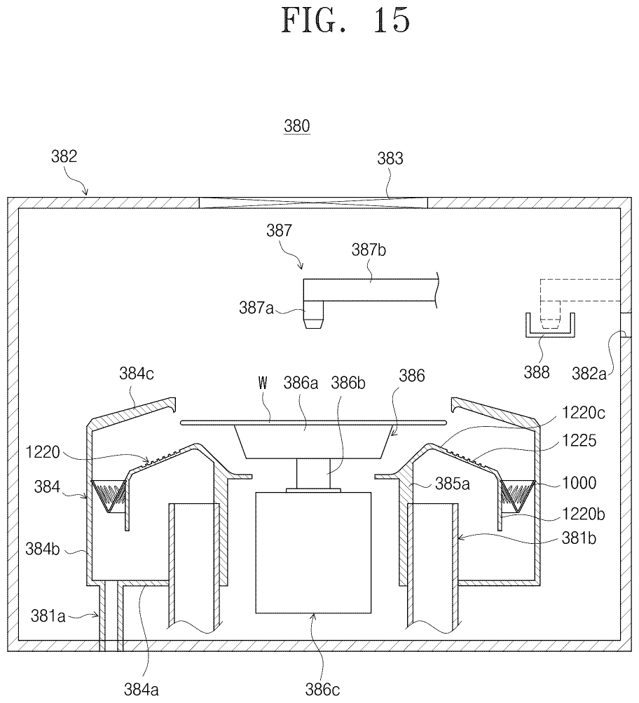

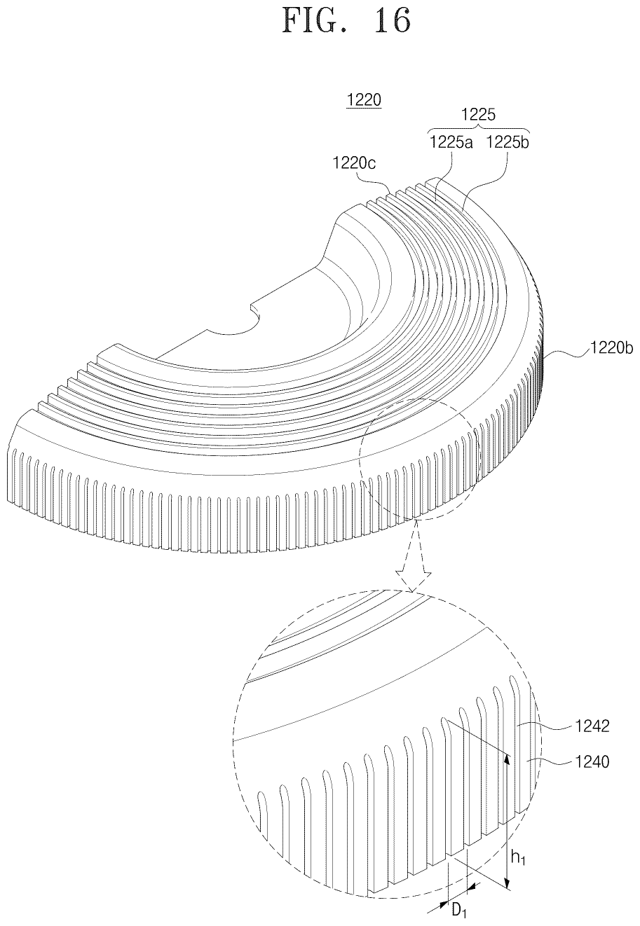

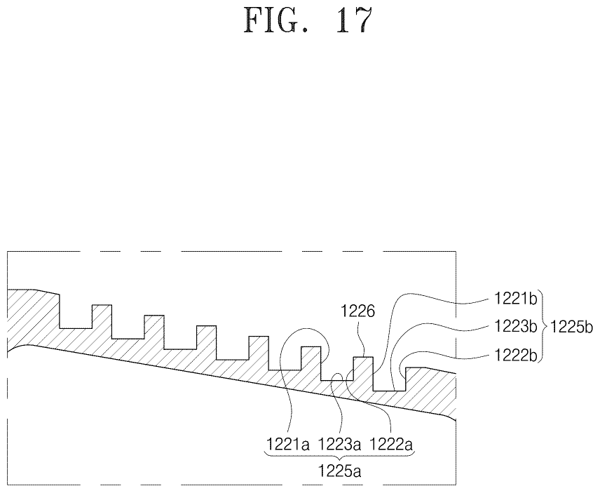

FIG. 15 is a cross-sectional view illustrating another embodiment of the guide cup according to the present invention, FIG. 16 is a perspective view illustrating the guide cup from FIG. 15, and FIG. 17 is a cross-sectional view illustrating a top wall of the guide cup of FIG. 15. The parts of FIGS. 15 to 17 that overlap those of the exemplary embodiment of FIG. 8 are not described. According to the exemplary embodiment of FIGS. 15 to 17, a top wall 1220c of a guide cup 1220 is formed with a first wall 1221, a second wall 1222, a bottom surface 1223, a retention groove 1225, and a step 1226. The first wall 1221 and the second wall 1222 are provided to face each other. The second wall 1222 is provided spaced apart from the first wall 1221 in a direction from the guide cup 385 toward the outer cup 384. The retention groove 1225 is defined by the second wall 1222 and a bottom surface 1223 extending between the first wall 1221 and the second wall 1222. The retention groove 1225 provides space for the cleaning liquid to pool. In one example, the height of the first wall 1221 is provided to be higher than the height of the second wall 1222. The retention groove 1225 that is relatively close to the support unit 386 is defined as a first retention groove 1225a, and the retention groove 1225 that is relatively far from the support unit 386 is defined as a second retention groove 1225b. The step 1226 is provided between the first retention groove 1225a and the second retention groove 1225b. The step 1226 ensures that the cleaning liquid that pools in the first retention groove 1225a stays in the first retention groove 1225a, rather than flowing directly into the second retention groove 1225b. The second retention groove 1225b is spaced from the first retention groove 1225a in a direction from the first retention groove 1225a toward the outer cup 384. In one example, the bottom surface 1223 of the first retention groove 1225a is provided at a higher position than the bottom surface 1223 of the second retention groove 1225b. Accordingly, the guide cup 385 is provided in a stepped shape that descends outwardly. In one example, the retention grooves 1225 are provided in a plurality in a ring shape along the circumferential direction of the top wall 385c. For example, the retention grooves 1225 may be provided in a plurality of concentric rings of different diameters.

The outer surface of the outer wall 1220b is provided with at least two guide grooves 1242 formed downwardly from the bottom end of the top wall 1220c. In one example, the guide groove 1242 is formed in a straight line downwardly from the bottom end of the top wall 1220c. For example, the guide groove 1242 may be formed in a vertical direction from the bottom end of the top wall 1220c to the lowermost end of the outer wall 1220b. In one example, the guide groove 1242 may be provided in a plurality equally spaced around the circumference of the outer wall 1220b. In one example, the spacing between the centers of the guide grooves 1242 may be provided shorter than the longitudinal length of the outer wall 1220b. In one example, the spacing between the centers of the guide grooves 1242 may be provided longer than the width of the guide grooves 1242. In one example, a cross-section of the guide groove 1242 may be provided in a semicircular shape.

Referring again to FIGS. 1 to 4, the interface module 500 connects the processing module 300 with an external exposure device 700. The interface module 500 includes an interface frame 501, a buffer unit 510, a cooling unit 520, a transfer mechanism 530, an interface robot 540, and an additional process chamber 560.

The top of the interface frame 501 may be provided with a fan filter unit forming a downward airflow therein. The buffer unit 510, the cooling unit 520, the transfer mechanism 530, the interface robot 540, and the additional process chamber 560 are disposed inside the interface frame 501.

The structure and arrangement of the buffer unit 510 and the cooling unit 520 may be the same or similar to those of the buffer unit 310 and the cooling unit 320 provided in the processing module 300. The buffer unit 510 and the cooling unit 520 are disposed adjacent to the end of the transfer chamber 350. The substrate W being transferred between the processing module 300, the cooling unit 520, the additional process chamber 560, and the exposure device 700 may temporarily reside in the buffer unit 510. The cooling unit 520 may be provided only at a height corresponding to the application block 300a between the application block 300a and the developing block 300b.

The transfer mechanism 530 may transfer the substrate W between the buffer units 510. The transfer mechanism 530 may also transfer the substrate W between the buffer unit 510 and the cooling unit 520. The transfer mechanism 530 may be provided with the same or similar structure as the transfer mechanism 330 of the processing module 300. Another transfer mechanism 531 may be further provided in a region opposite to the region where the transfer mechanism 530 is provided relative to the buffer unit 510.

The interface robot 540 is disposed between the buffer unit 510 and the exposure device 700. The interface unit 540 is provided to transfer the substrate W between the buffer unit 510, the cooling unit 520, the additional process chamber 560, and the exposure device 700. The interface robot 540 includes a hand 542 on which the substrate W is placed, and the hand 542 may be provided to be movable forwardly and backwardly, rotatable about the third direction 16, and movable along the third direction 16.

The additional process chamber 560 may perform a predetermined additional process before the substrate W processed in the application block 300a is loaded to the exposure device 700. Optionally, the additional process chamber 560 may perform a predetermined additional process before the substrate W processed in the exposure device 700 is loaded to the developing block 300b. In one example, the additional process may be an edge exposure process that exposes an edge region of the substrate W, or a top surface cleaning process that cleans the top surface of the substrate W, or a bottom surface cleaning process that cleans the bottom surface of the substrate W, or an inspection process that performs a predetermined inspection on the substrate W. A plurality of additional process chambers 560 may be provided, which may be stacked on top of each other.

In the example described above, the liquid treating chamber provided in the application block 300a has been described as an example, but is not limited thereto. For example, a trap ring 1000 may also be installed in the liquid treating chamber provided in the developing block 300b.

In the example described above, the case where the bottom end of the first sidewall 1100 and the bottom end of the second sidewall 1200 of the trap ring 1000 are in contact with each other such that the cross-section of the trap ring 1000 is V-shaped, U-shaped, or W-shaped has been described as an example, but the present invention is not limited thereto. Any shape that is capable of capturing the treatment liquid is sufficient, for example, the shape including a bottom wall connecting the bottom end of the first sidewall 1100 and the bottom end of the second sidewall 1200.

In addition, in the example described above, the case where the exhaust hole 1300 has a circular shape has been described, but the present invention is not limited thereto. For example, the exhaust holes 1300 may be provided in any shape that may provide a passageway for exhaust gas and treatment liquid, and cleaning liquid.

In addition, in the example described above, the case where the plurality of exhaust holes 1300 is provided has been described, but the present invention is not limited thereto. For example, only one exhaust hole 1300 may be provided, and the bottom surface of the trap ring 1000 may be provided with a downward slope toward the exhaust hole.

In addition, in the example described above, the case where the trap ring 1000 has the inner protrusion 1110 engaged with the groove in the guide cup 385 and the outward protrusion 1210 engaged with the groove in the outer cup 384, but the trap ring 1000 may also be installed by forming protrusions on the outer wall 385b of the guide cup 385 and the sidewall 384b of the outer cup 384 and resting on the respective protrusions of the inner protrusion 1110 and the outer protrusion 1210. However, the present invention is not limited thereto, and any other means of securing the trap ring to the gap V is sufficient.

In addition, in the example described above, the case where the trap ring 1000 is coupled to the top end of the outer wall 385b of the guide cup 385 has been described, but the present invention is not limited thereto. For example, the trap ring 1000 may be coupled to the bottom end of the outer wall 385b of the guide cup 385.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even if not specifically illustrated or described. The modifications are not to be considered as departing from the spirit and scope of the disclosure, and all such modifications that would be obvious to one of ordinary skill in the art are intended to be included within the scope of the accompanying claims.

What is claimed is:

1. An apparatus for treating a substrate, the apparatus comprising:
an outer cup having a treatment space with an open top;
a support unit for supporting a substrate in the treatment space;
a guide cup disposed in the treatment space and arranged to surround the support unit;
a liquid supply unit for supplying a treatment liquid to a top surface of the substrate supported by the support unit; and
a trap ring disposed in a gap between the guide cup and the outer cup to capture the treatment liquid flowing through the gap,
wherein the trap ring is formed with an exhaust hole through which gas flowing through the gap passes, and
the trap ring has a capture space for capturing the treatment liquid on a top surface thereof.

2. The apparatus of claim 1, wherein the trap ring includes:
a first sidewall; and
a second sidewall, and
the first sidewall is positioned more adjacent to the outer cup than the second sidewall, and
the capture space is provided as a space between the first sidewall and the second sidewall.

3. The apparatus of claim 2, wherein the first sidewall is provided to be away from the outer cup as the first sidewall goes downwardly.

4. The apparatus of claim 2, wherein the second sidewall is provided to be away from the guide cup as the second sidewall goes downwardly.

5. The apparatus of claim 2, wherein the first sidewall is provided with a downward slope in a direction away from the outer cup, and
the second sidewall is provided with a downward slope in a direction away from the guide cup.

6. The apparatus of claim 5, wherein a bottom end of the first sidewall and a bottom end of the second sidewall are in contact with each other.

7. The apparatus of claim 2, wherein at least one of the first sidewall or the second sidewall is formed with the exhaust hole.

8. The apparatus of claim 2, further comprising:
an outer protrusion extending from a top end of the first sidewall in a direction toward the outer cup, and coupled to the outer cup; and
an inner protrusion extending from a top end of the second sidewall in a direction toward the guide cup, and coupled to the guide cup.

9. The apparatus of claim 2, wherein an inclination angle of the first sidewall and an inclination angle of the second sidewall with respect to an axis perpendicular to the ground are the same.

10. The apparatus of claim 1, further comprising:
a ring cleaning unit for supplying a cleaning liquid to clean the trap ring.

11. The apparatus of claim 10, wherein the guide cup includes:
a top wall provided with a downward slope in a direction toward the outer cup; and
an outer wall extending downwardly from the top wall,
the outer cup includes a sidewall provided parallel to a perpendicular direction,
the trap ring is positioned between the outer wall and the sidewall, and
the ring cleaning unit further includes a ring cleaning nozzle for supplying a cleaning liquid to the top wall.

12. The apparatus of claim 11, wherein the outer cup includes:
a bottom wall extending inwardly from the sidewall to provide a discharge space for liquid at a lower portion of the guide cup; and
a discharge hole connected with the discharge space to discharge the liquid, and
the outer wall is provided in a position opposite the discharge hole.

13. The apparatus of claim 10, wherein the treatment liquid is a photosensitive liquid, and the cleaning liquid is a thinner.

14. The apparatus of claim 13, wherein the photosensitive liquid has a viscosity of 1000 cP or more.

15. An apparatus for applying a resist liquid onto a substrate, the apparatus comprising:
an outer cup having a treatment space with an open top;
a support unit for supporting and rotating a substrate in the treatment space;
a guide cup disposed in the treatment space, and arranged to surround the support unit;
a liquid supply unit for supplying a resist liquid to a top surface of the substrate supported by the support unit;
a trap ring disposed in a gap between the guide cup and the outer cup to capture the treatment liquid flowing through the gap; and
a ring cleaning unit for supplying a cleaning liquid to clean the trap ring, wherein the trap ring includes:
a first sidewall provided with a downward slope in a direction away from the outer cup; and
a second sidewall provided with a downward slope in a direction away from the guide cup,
a capture space is formed between the first sidewall and the second sidewall to capture the resist liquid that has been scattered from the substrate, and
an exhaust hole is formed in at least one of the first sidewall and the second sidewall through which gas flowing through the gap passes.

16. The apparatus of claim 15, wherein the cleaning liquid is a thinner.

17. The apparatus of claim 15, wherein the guide cup includes:
a top wall provided with a downward slope in a direction toward the outer cup; and
an outer wall extending downwardly from the top wall, and
the trap ring is positioned between the outer wall and the sidewall, and
the ring cleaning unit includes an intermediate nozzle for supplying a cleaning liquid directly to the top wall.

18. The apparatus of claim 17, wherein the outer cup includes:
a bottom wall extending from the sidewall in a direction toward the guide cup to form a liquid discharge space at a lower portion of the guide cup; and
a discharge hole for discharging the liquid from the discharge space, and
the outer wall is provided in a position opposite the discharge hole, and
the bottom wall is provided with a downward slope toward the discharge hole.

19. An apparatus for treating a substrate, the apparatus comprising:
an outer cup having a treatment space with an open top;
a support unit for supporting a substrate in the treatment space;
a guide cup disposed in the treatment space and arranged to surround the support unit;
a liquid supply unit for supplying a treatment liquid to a top surface of the substrate supported by the support unit;
a trap ring disposed in a gap between the guide cup and the outer cup to capture the treatment liquid flowing through the gap; and
a ring cleaning unit for supplying a cleaning liquid cleaning the trap ring,
wherein the guide cup includes:
a top wall provided with a downward slope in a direction toward the outer cup; and
an outer wall extending downwardly from the top wall, and
the outer cup includes:
a sidewall provided parallel to the outer wall; and
a bottom wall extending from the sidewall in a direction toward the guide cup,
the bottom wall is formed with a discharging pipe for discharging the treatment liquid and the cleaning liquid, and an exhaust pipe for exhausting the treatment space,
the outer wall is provided in a position opposite the discharge hole, and
the bottom wall is provided with a downward slope toward the discharge hole,
the trap ring includes:
a first sidewall; and
a second sidewall,
the first sidewall is positioned more adjacent to the outer cup than the second sidewall, and
a bottom end of the first sidewall and a bottom end of the second sidewall are in contact with each other to provide a capture space for capturing the treatment liquid, and
each of the first sidewall and the second sidewall is formed with an exhaust hole through which gas flowing through the gap passes.

20. The apparatus of claim 19, wherein the top wall is formed with a retention groove defined by a first wall, a second wall spaced from the first wall in a direction from the guide cup toward the outer cup, and a bottom surface extending from the first wall and the second wall,
a height of the first wall is provided to be higher than a height of the second wall,
the retention grooves are provided in a plurality in a ring shape along a circumferential direction of the top wall,
the retention groove includes:
a first retention groove; and
a second retention groove spaced from the first retention groove in a direction from the first retention groove toward the outer cup,
a bottom surface of the first retention groove is provided at a higher position than a bottom surface of the second retention groove, and
an outer surface of the outer wall is provided with at least two guide grooves formed downwardly from a bottom end of the top wall.
